(19) United States
(12) Patent Application Publication
(10) Pub. No.: US 2011/0151379 A1
(43) Pub. Date: Jun. 23, 2011

(54) BLACK MATRIX COMPOSITION WITH HIGH LIGHT-SHIELDING AND IMPROVED ADHESION PROPERTIES

(75) Inventors: Dong Chang Choi, Daejeon (KR); Kyung Soo Choi, Hanam-si (KR); Ho Chan Ji, Daejeon (KR); Geun Young Cha, Daejeon (KR); Sang Chul Lee, Daejeon (KR)

(73) Assignee: LG CHEM, LTD., Seoul (KR)

(21) Appl. No.: 12/965,715

(22) Filed: Dec. 10, 2010

(30) Foreign Application Priority Data
Dec. 22, 2009 (KR) 10-2009-0128708

(51) Int. Cl. G03F 7/004

(52) U.S. Cl. 430/270.1

(57) ABSTRACT

The present invention relates to a black matrix photosensitive resin composition having high light-shielding and improved adhesion properties and a black matrix for a liquid crystal display including the same. The black matrix photosensitive resin composition comprises an alkali-soluble binder resin, a multi-functional monomer having an ethylenic unsaturated double bond, a photopolymerization initiator, an adhesion accelerator, a solvent, and a colorant comprising black pigments. A Cardo type binder is mixed in an amount of 10 to 90 wt % and an acryl type binder is mixed in an amount of 10 to 90 wt % based on a total weight of the alkali-soluble binder resin including the Cardo type binder and the acryl type binder.

Priority to Korean patent application number 10-2009-0128708 filed on Dec. 22, 2009, the entire disclosure of which is incorporated by reference herein, is claimed.

### BACKGROUND OF THE INVENTION

1. Field of the Invention

The present invention relates to a black matrix photosensitive resin composition having high light-shielding and improved adhesion properties and a black matrix for a liquid crystal display including the same.

2. Discussion of the Related Art

In general, a black pattern on the lattice, also called a black matrix, is disposed between the color pixels of a color filter in order to improve contrast. A conventional black matrix is made of chromium (Cr). In this process, chromium (Cr) is deposited on the entire glass substrate and the pattern is formed through etching processing. The process requires high expenses and has problems, such as high reflexibility of chromium (Cr) and environmental pollution resulting from chromium (Cr) waste liquid. For the above reasons, active research is being carried out on a resin black matrix using a pigment spray method enabling minute processing.

Further, research is being performed on the manufacture of a black composition using coloring pigments other than carbon black. The coloring pigments other than carbon black have low light-shielding properties, resulting in a very high mixing ratio of the color pigments other than carbon black. Accordingly, there are problems in that the viscosity of the composition is increased, making handling thereof difficult, or the strength of a formed film or adhesion with a substrate is greatly low.

Lots of researches are being carried out in line with the need for continued improved performance in the industry. As researches into a photosensitive resin composition, Japanese Patent Application Laid-Open No. 2005-156930 discloses a color filter composition using a binder newly developed for improved sensitivity, and Japanese Patent Application Laid-Open No. 2005-338328 discloses a black resin composition having improved sensitivity using a high-sensitivity photopolymerization initiator. Further, Japanese Patent Application Laid-Open No. 2004-347916 discloses a black matrix composition having improved sensitivity by adding a photopolymerization initiator and an organic phosphoric acid compound to the composition. Moreover, Japanese Patent Application Laid-Open Nos. 2005-215378, 2005-227797, 2005-275218, 2000-227654, Hei11-326606, and Hei11-143056, and U.S. Pat. No. 5,866,298, and Korean Patent Nos. 2006-0076413 and 2002-0031093 disclose the development of a black matrix.

Meanwhile, the market share of the LCD in the flat display field is sharply increased. There is a continued need for high light-shielding properties in every area of notebooks, monitors, and TV. New technologies for a slim display and a wider screen are being developed. In order to satisfy the requirements, technologies for realizing a visual design, slimness, and a wider screen even by 1 inch are being applied by using a minimum area even in the coalesced portion of the upper and rear plates of a module. In particular, in order to maximize the mobile characteristic with a gradual increase of the mobile market, schemes for slimness in the module itself, a reduction in equipment, and the maximum of a display are taken into considered.

A new form of a coalescence method not the existing coalescence method is used as one of the schemes. In the existing coalescence method, coalescence is performed using the edges of glass and a black matrix at the same time, but the efficiency of a display in the panel is low because coalescence is performed using glass larger than an area actually seen. In the new coalescence method, however, in order to increase the efficiency of a display, coalescence is performed only in a black matrix portion without using glass. Accordingly, the efficiency of a display in the panel can be maximized.

The existing coalescence method has no significant problem in pressure applied when coalescence is performed and in the adhesion properties of a sealant during a reliability process because the coalescence is performed using the glass and the black matrix at the same time. However, in case where the coalescence is performed only in the black matrix portion, pressure applied when the coalescence is performed and the adhesion properties of a black matrix during a reliability process become problematic, leading to a seal breakdown and the breakdown of a conductive film.

### SUMMARY OF THE INVENTION

It is not easy to secure a composition, satisfying both a high Optical Density (OD) characteristic and adhesion properties, because the two conditions have a trade-off relation. In particular, as described above, there is an increasing demand for the adhesion properties of a black matrix because of the introduction of a new process.

It was found that a binder from among several components greatly affected the adhesion properties as a result of researches into each of the components of a composition so that the adhesion properties were not deteriorated while having a high OD characteristic. In order to secure the process characteristics of a black matrix, a Cardo type binder has to be indispensably used. However, it was found that the Cardo type binder was weak in the adhesion properties, whereas an acryl type binder was difficult to secure the process characteristics when it was applied to a black matrix for a high OD, but had excellent adhesion properties.

Accordingly, the present invention has been made keeping in mind the above problems occurring in the prior art, and an object of the present invention is to provide a black matrix photosensitive resin composition which is capable of improving the adhesion properties and also optimizing the process conditions of a black matrix for a high OD by mixing a Cardo type and an acryl type binder at a specific ratio, and a black matrix for a liquid crystal display including the same.

In accordance with an aspect of the present invention, there is provided a black matrix photosensitive resin composition for a liquid crystal display, comprising an alkali-soluble binder resin, a multi-functional monomer having an ethylenic unsaturated double bond, a photopolymerization initiator, an adhesion accelerator, a solvent, and a colorant comprising black pigments, wherein a Cardo type binder is mixed in an amount of 10 to 90 wt % and an acryl type binder is mixed in an amount of 10 to 90 wt % based on the total weight of the alkali-soluble binder resin including the Cardo type binder and the acryl type binder. Accordingly, a black matrix with high light-shielding and excellent adhesion properties can be fabricated.

### DETAILED DESCRIPTION OF THE EMBODIMENTS

Hereinafter, embodiments of the present invention are described in detail with reference to the accompanying drawings so that they can be readily implemented by those skilled in the art.

A photosensitive resin composition of the present invention is a black matrix photosensitive resin composition, comprising an alkali-soluble binder resin, a multi-functional monomer having an ethylenic unsaturated double bond, a photopolymerization initiator, an adhesion accelerator, a solvent, and a colorant including black pigments, wherein a Cardo type binder is mixed in an amount of 10 to 90 wt % and an acryl type binder is mixed in an amount of 10 to 90 wt % based on the total weight of the alkali-soluble binder resin including the Cardo type binder and the acryl type binder.

Accordingly, both a process characteristic effect due to the Cardo type binder and an adhesion effect due to the acryl type binder can be realized. If the amount of the Cardo type binder is 10% or lower, it is difficult to secure the process characteristic of a black matrix for a high OD. If the amount of the Cardo type binder is 90% or higher, the adhesion properties are deteriorated, leading to a disadvantageous characteristic. Further, if the amount of the acryl type binder is 10% or lower, it is difficult to expect improved adhesion properties. If the amount of 90% or higher, the adhesion properties are excellent, but the process characteristic is deteriorated.

More particularly, if the Cardo type binder is mixed in an amount of 25 to 70 wt % and the acryl type binder is mixed in an amount of 30 to 75 wt % based on the total weight of the alkali-soluble binder resin including the Cardo type binder and the acryl type binder, both the process characteristic and the adhesion properties can be secured to the optimal extent.

It is preferred that the photosensitive resin composition of the present invention includes a) the alkali-soluble binder resin of 1 to 10 parts by weight; b) the multi-functional monomer of 1 to 10 parts by weight, having an ethylenic unsaturated double bond; c) the photopolymerization initiator of 0.1 to 10 parts by weight; d) the adhesion accelerator of 0.01 to 1 parts by weight; e) the solvent of 70 to 90 parts by weight; and f) the colorant of 35 to 85 parts by weight, including black pigments.

The Cardo type binder used in the present invention can include a repetition unit represented by the following formula 1.

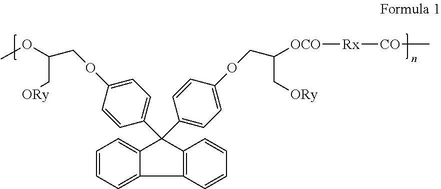

In the formula,

Rx is a structure for forming an ester bond through an additional reaction of carboxylic anhydride of 5-membered rings. For example, succinic anhydride, methylsuccinic anhydride, 2,2-dimethylsuccinic anhydride, isobutenylsuccinic anhydride, 1,2-cyclohexenedicarbonic anhydride, hexahydro-4-methyl phthalic anhydride, itaconic anhydride, tetrahydro phthalic anhydride, 5-norbornene-2,3-dicarbonic anhydride, methyl-5-norbornene-2,3-dicarbonic anhydride, 1,2,3,4-cyclobutanetetracarbonic dianhydride, maleic anhydride, citraconic anhydride, 2,3,-dimethylmaleic anhydride, 1-cyclopentene-1,2-dicarbonic dianhydride, 3,4,5,6-tetrahydrophthalic anhydride, phthalic anhydride, bisphthalic anhydride, 4-methylphthalic anhydride, 3,6-dichlorophthalic anhydride, 3-hydrophthalic anhydride, 1,2,4-benzenetricarboxylic anhydride, 4-nitrophthalic anhydride, and diethyleneglycol-1,2-bistrimaleic anhydride can be selected and used, but not limited thereto.

As another structure of Rx, diisocyanate may be used instead of the carboxylic anhydride. For example, the diisocyanate can include trimethylenediisocyanate, tetramethylenediisocyanate, hexamethylenediisocyanate, pentamethylenediisocyanate, 1,2-propylenediisocyanate, 2,3-butylenediisocyanate, 1,3-butylenediisocyanate, dodecamethylenediisocyanate, 2,4,4-trimethyl hexamethylene diisocyanate, w,w′-diisocyanate-1,3-dimethylbenzene, w,w′-diisocyanate-1,4-dimethylbenzene, w,w′-diisocyanate-1,3-diethylbenzene, 1,4-tetramethyl xylene diisocyanate, 1,3-tetramethyl xylene diisocyanate, isophoronediisocyanate, 1,3-cyclopentanediisocyanate, 1,3-cyclohexenediisocyanate, 1,4-cyclohexenediisocyanate, methyl-2,4-cyclohexenediisocyanate, methyl-2,6-cyclohexene diisocyanate, 4,4′-methylene bisisocyanate methylcyclohexene, 2,5-isocyanatemethyl bicyclo[2,2,2]heptane, and 2,6-isocyanatemethyl bicyclo[2,2,1]heptane, but not limited thereto.

One selected from among hydrogen, acryloyl, and methacryloyl can be used as Ry.

n is the repetition unit.

Meanwhile, it is preferred that the weight average molecular weight (i.e., a value measured by a Gel Permeation Chromatograph (GPC)) of the Cardo type binder mixed in the alkali-soluble binder be in the range of 1,000 to 30,000, more preferably, 1,500 to 10,000. It is preferred that an acid value be in the range of 10 KOH mg/g to 200 KOH mg/g, more preferably, 30 KOH mg/g to 150 KOH mg/g.

It is preferred that the acryl type binder used in the present invention include monomer, providing the mechanical strength of a film, and a monomer providing alkali solubility. For example, one kind, preferably, two or more selected from the group, consisting of unsaturated carboxylic esters, such as benzyl(metha)acrylate, methyl(metha)acrylate, ethyl(metha)acrylate, butyl(metha)acrylate, dimethylaminoethyl(metha)acrylate, isobutyl(metha)acrylate, t-butyl(metha)acrylate, cyclohexyl(metha)acrylate, isobornyl(metha)acrylate, ethyl hexyl-(metha)acrylate, 2-phenoxyethyl(metha) acrylate, tetrahydrofurfuryl(metha)acrylate, hydroxyethyl(metha)acrylate, 2-hydroxypropyl(metha)acrylate, 2-hydroxy-3-chloropropyl(metha)acrylate, 4-hydroxybutyl(metha)acrylate, acyloctyloxy-2-hydroxypropyl(metha)acrylate, glycerol(metha)acrylate, 2-methoxyethyl(metha)acrylate, 3-methoxybutyl (metha)acrylate, ethoxydiethyleneglycol(metha)acrylate, methoxytriethyleneglycol (metha)acrylate, methoxytripropyleneglycol(metha)acrylate, poly(ethyleneglycol) methylether(metha)acrylate, phenoxydiethyleneglycol(metha)acrylate, p-nonylphenoxypolyethyleneglycol(metha)acrylate, P-nonylphenoxypolypropyleneglycol(metha)acrylate, glycidyl(metha)acrylate, tetrafluoropropyl(metha)acrylate, 1,1,1,3,3,3-hexafluoroisopropyl(metha) acrylate, octafluoropentyl(metha)acrylate, heptadecafluorodecyl(metha)acrylate, tribromophenyl(metha)acrylate, dicyclofentanylmethacrylate, dicyclopentenylmethacrylate, dicyclopentenyloxyethylacrylate, isobornylmethacrylate, adamenthylmethacrylate, stearylmethacrylate, oxylmethacrylate, laurylmethacrylate, methyl α-hydroxymethyl acrylate, ethyl α-hydroxymethyl acrylate, propyl α-hydroxymethyl acrylate, and butyl α-hydroxymethyl acrylate; aromatic vinyls, such as styrene, α-methylstyrene, (o,m,p)-vinyl toulene, (o,m,p)-methoxy styrene, and (o,m,p)-chloro styrene; unsaturated ethers, such as vinyl methyl ether, vinyl ethyl ether, and allyl glycidyl ether; unsaturated imides, such as N-phenyl maleimide, N-(4-chlorophenyl) maleimide, N-(4-hydroxyphenyl) maleimide, and N-cyclohexyl maleimide; and maleic anhydrides, such as maleic anhydride and methyl maleic anhydride, can be used as the monomer providing the mechanical strength of a film, but not limited thereto.

It is preferred that one or more selected from the group, consisting of (metha)acrylic acid, crotonate, itaconic acid, maleic acid, fumarate, monomethyl maleic acid, 5-norbornene-2-carboxylic acid, mono-2-((metha)acryloyloxy)ethyl phthalate, mono-2-((metha)acryloyloxy)ethyl succinate, and w-carboxy polycaprolactone mono(metha)acrylate, be used as the monomer providing the alkali solubility, but not limited thereto.

Meanwhile, it is preferred that the weight average molecular weight (i.e., a value measured by a Gel Permeation Chromatograph (GPC)) of the acryl type binder mixed in the alkali-soluble binder be in the range of 1,000 to 50,000, more preferably, 2,000 to 30,000. It is preferred that an acid value be in the range of 10 KOH mg/g to 200 KOH mg/g, more preferably, 30 KOH mg/g to 150 KOH mg/g.

A compound, having at least one unsaturated radical which can be subjected to addition and polymerization in molecules and having a boiling point of 100 or more, or a multi-functional monomer into which caprolactone has been introduced can be used either solely or in combinations as the multi-functional monomer having the ethylenic unsaturated double bond.

One or more selected from the group, consisting of a mono functional monomer, such as polyethyleneglycol mono(metha)acrylate, polypropyleneglycol mono(metha)acrylate, and phenoxyethyl(metha)acrylate; and a multi-functional monomer, such as polyethyleneglycol(metha)acrylate, polypropyleneglycol (metha)acrylate, trimethylolethane triacrylate, trimethylolpropane triacrylate, neopentylglycol(metha)acrylate, pentaerythritol tetraacrylate, pentaerythritol triacrylate, dipentaerythritol pentaacrylate, and dipentaerythritol hexacrylate, can be used as the compound having at least one unsaturated radical which can be subjected to addition and polymerization in molecules and having a boiling point of 100 or more, but not limited thereto.

One or more selected from the group, consisting of KAYARAD DPCA-20,30,60,120 introduced into dipentaerythritol, KAYARAD TC-110S introduced into tetrahydrofuryl acrylate, and KAYARAD HX-220 and KAYARAD HK-620 introduced into neopentylglycol hydroxypivalate; EPOXY ESTER 200PA, EPOXY ESTER 3002M, EPOXY ESTER 3002A, and EPOXY ESTER 3000M (manufactured by Kyoeisha Chemical Co., Ltd.); and UA306H, UA306T, UA3061, UA510H, UF8001, and U-324A, U15HA, and U-4HA which are urethane acrylate types, can be used as the multi-functional monomer into which the caprolactone has been introduced, but not limited thereto.

Further, it is preferred that the multi-functional monomer having the ethylenic unsaturated double bond be included in an amount of 1 to 20 parts by weight based on the total weight of the photosensitive resin composition (i.e., 5 to 50 wt % on the basis of the solids of the photosensitive resin composition). If the amount of the multi-functional monomer is less than 1 parts by weight, photo sensitivity or the strength of a coating film is deteriorated. If the amount of the multi-functional monomer is more than 20 parts by weight, the adhesiveness of a photosensitive resin layer becomes excessive, leading to an insufficient strength of a film and a lost pattern when development is performed. More preferably, the amount of the multi-functional monomer is 1 to 10 parts by weight.

The photopolymerization initiator used in the present invention is material which accelerates crosslinking by generating radicals with light. It is preferred that one or more selected from the group, consisting of an acetophenone type compound, a biimidazole type compound, a triazine type compound, and an oxime type compound, be used.

The acetophenone type compound which can be used as the photopolymerization initiator includes 2-hydroxy-2-methyl-1-phenylpropane-1-one, 1-(4-isopropylphenyl)-2-hydroxy-2-methylpropane-1-one, 4-(2-hydroxyethoxy)-phenyl-(2-hydroxy-2-propyl)ketone, 1-hydroxycyclohexylphenylketone, benzoinmethyl ether, benzomethyl ether, benzoinisobutyl ether, benzoinbutyl ether, 2,2-dimethoxy-2-phenylacetophenone, 2-methyl-(4-methylthio)phenyl-2-morpholino-1-propane-1-one, 2-benzyl-2-dimethylamino-1-(4-morpholinophenyl)-butane-1-one, 2-(4-bromo-benzyl-2-dimethylamino-1-(4-morpholinophenyl)-butane-1-one, or 2-methyl-1-[4-(methylthio)phenyl]-2-morpholinopropane-1-one. The biimidazole type compound which can be used as the photopolymerization initiator includes 2,2-bis(2-chlorophenyl)-4,4′,5,5′-tetraphenyl biimidazole, 2,2′-bis(o-chlorophenyl)-4,4′,5,5′-tetrakis(3,4,5-trimethoxyphenyl)-1,2′-biimidazole, 2,2′-bis(2,3-dichlorophenyl)-4,4′,5,5′-tetraphenyl biimidazole, or 2,2′-bis(o-chlorophenyl)-4,4,5,5′-tetraphenyl-1,2′-biimidazole. The triazine type compound which can be used as the photopolymerization initiator includes 3-{4-[2,4-bis(trichloromethyl)-s-triazine-6-yl]phenylthio}propionic acid, 1,1,1,3,3,3-hexafluoroisopropyl-3-{4-[2,4-bis(trichloromethyl)-s-triazine-6-yl]phenylthio}propionic acid, ethyl-2-{4-[2,4-bis(trichloromethyl)-s-triazine-6-yl]phenylthio}acetate, 2-epoxyethyl-2-{4-[2,4-bis(trichloromethyl)-s-triazine-6-yl]phenylthio}acetate, cyclohexyl-2-{4-[2,4-bis(trichloromethyl)-s-triazine-6-yl]phenylthio}acetate, benzyl-2-{4-[2,4-bis(trichloromethyl)-s-triazine-6-yl]phenylthio}acetate, 3-{chloro-4-[2,4-bis(trichloromethyl)-s-triazine-6-yl]phenylthio}propionic acid, 3-{4-[2,4-bis(trichloromethyl)-s-triazine-6-yl]phenylthio}propioneamide, 2,4-bis(trichloromethyl)-6-p-methoxystyryl-s-triazine, 2,4-bis(trichloromethyl)-6-(1-p-dimethylaminophenyl)-1,3,-butadienyl-s-triazine, or 2-trichloromethyl-4-amino-6-p-methoxystyryl-s-triazine. The oxime type compound which can be used as the photopolymerization initiator includes 1,2-octadion,-1-(4-phenylthio)phenyl,-2-(o-benzoyloxime) (CGI124 manufactured by Ciba-Geigy Ltd.), ethanone,-1-(9-ethyl)-6-(2-methylbenzoyl-3-yl)-,1-(O-acetyloxime)(CGI242), or N-1919 (manufactured by ADEKA Corporation).

Further, it is preferred that the photopolymerization initiator of 1 to 300 parts by weight be used for every 100 parts by weight which is the sum of the multi-functional monomer, having the ethylenic unsaturated double bond, and the unsaturated double bond, included in the binder resin, in the photosensitive resin composition. In particular, it is preferred that the acetophenone type compound of 1 to 30 parts by weight, the biimidazole type compound of 1 to 30 parts by weight, the triazine type compound of 1 to 30 parts by weight, and the oxime type compound of 1 to 30 parts by weight be used.

Meanwhile, the photopolymerization initiator is an auxiliary component and it can further includes a photo-crosslinking sensitizer of 0.01 to 10 parts by weight which accelerates the generation of radicals, or a curing accelerator of 0.01 to 10 parts by weight which accelerates curing.

Here, one or more selected from the group, consisting of a benzophenone type compound, such as benzophenone, 4,4-bis(dimethylamino)benzophenone, 4,4-bis(diethylamino)benzophenone, 2,4,6-trimethylaminobenzophenone, methyl-o-benzoylbenzoate, 3,3-dimethyl-4-methoxybenzophenone, and 3,3,4,4-tetra(t-butylperoxycarbonyl)benzophenone; a fluorenone type compound, such as 9-fluorenone, 2-chloro-9-prorenone, and 2-methyl-9-fluorenone; a thioxanthen type compound, such as thioxanthen, 2,4-diethyl thioxanthen, 2-chloro thioxanthen, 1-chloro-4-propyloxy thioxanthen, isopropylthioxanthen, and diisopropylthioxanthen; a xanthone type compound, such as xanthone and 2-methylxanthone; an anthraquinone type compound, such as anthraquinone, 2-methyl anthraquinone, 2-ethyl anthraquinone, t-butyl anthraquinone, and 2,6-dichloro-9,10-anthraquinone; an acridine type compound, such as 9-phenylacridine, 1,7-bis(9-acridinyl)heptane, 1,5-bis(9-acridinylpentane), and 1,3-bis(9-acridinyl)propane; a dicarbonyl compound, such as benzyl, 1,7,7-trimethyl-bicyclo[2,2,1]heptane-2,3-dion, and 9,10-phenanthrenequinone; a phosphine oxide type compound, such as 2,4,6-trimethylbenzoyl diphenylphosphine oxides and bis(2,6-dimethoxybenzoyl)-2,4,4-trimethylpentyl phosphine oxides; a benzoate type compound, such as methyl-4-(dimethylamino)benzoate, ethyl-4-(dimethylamino)benzoate, and 2-n-butoxyethyl-4-(dimethylamino)benzoate; an amino synergist, such as 2,5-bis(4-diethylaminobenzal)cyclopentanone, 2,6-bis(4-diethylaminobenzal)cyclohexanone, and 2,6-bis(4-diethylaminobenzal)-4-methyl-cyclopentanone; a coumarin type compound, such as 3,3-carbonylvinyl-7-(diethylamino)coumarin, 3-(2-benzothiazolyl)-7-(diethylamino)coumarin, 3-benzoyl-7-(diethylamino)coumarin, 3-benzoyl-7-methoxy-coumarin, and 10,10-carbonylbis[1,1,7,7-tetramethyl-2,3,6,7-tetrahydro-1H,5H,11H-C1]-benzopyrano[6,7,8-ij]-quinolizin-11-one; a calcon compound, such as 4-diethylamino calcon and 4-azidebenzalacetophenone; 2-benzoylmethylene; and 3-methyl-b-naphthothiazolin, can be used as the photo-crosslinking sensitizer.

One or more selected from the group, consisting of 2-mercaptobenzoimidazole, 2-mercaptobenzothiazole, 2-mercaptobenzooxazole, 2,5-dimercapto-1,3,4-thiadiazol, 2-mercapto-4,6-dimethylaminopyridine, pentaerythritol-tetrakis(3-mercaptopropionate), pentaerythritol-tris(3-mercaptopropionate), pentaerythritol-tetrakis(2-mercaptoacetate), pentaerythritol-tris(2-mercaptoacetate), trimethylolpropane-tris(2-mercaptoacetate), and trimethylolpropane-tris(3-mercaptopropionate), can be used as the curing accelerator.

One or more selected from among methaacryloyl silane coupling agents, such as methacryloyloxy propyltrimethoxy silane, methacryloyloxy propyldimethoxy silane, methacryloyloxy propyltriethoxy silane, and methacryloyloxy propyldimethoxysilane can be used as the adhesion accelerator used in the present invention. One or more selected from among octyltrimethoxy silane, dodecyltrimethoxy silane, and octadecyltrimethoxy silane can be used as the alkyl trimethoxy silane.

It is preferred that the solvent used in the present invention include at least two or more of methyl-3-methoxy propionate (144), ethyleneglycol methylether (125), ethyleneglycol ethylether (135), ethyleneglycol diethylether (121), dibutylether (140), ethylpyruvate (144), propyleneglycol methylether (121), propyleneglycol methylether acetate (146), n-butylacetate (125), isobutylacetate (116), amylacetate (149), isoamylacetate (143), butylpropionate (146), isoamylpropionate (156), ethylbutyrate (120), propyl butyrate (143), methyl-3-methoxyisobutyrate (148), methylglycolrate (150), methyl lactate (145), ethyl lactate (154), methyl-2-hydroxyisobutylrate (137), ethylethoxyacetate (156), 2-methoxyethylacetate (145), ethyleneglycolmethyletheracetate (145), 2-ethoxyethylacetate (156), dibutylether (140), cyclopentanone (131), cyclohexanone (155), 2-hexanone (127), 3-hexanone (123), 5-methyl-2-hexanone (145), 2-heptanone (150), 3-heptanone (148), 4-heptanone (145), 2-methyl-3-heptanone (159), 1-methoxy-2-propanol (118), ethyl-2-hydroxy-propionate (154), and ethyl-3-methoxypropionate (158), 2-methoxy ethylether (162), 3-methoxybutylacetate (170), 2-ethoxyethyl ether (185), 2-butoxyethanol (171), 3-ethoxy-propanol (161), diethyleneglycoldodecylether (169), dipropyleneglycolmethylether (188), 2,6-dimethyl-4-heptanone (169), 2-octanone (173), 3-octanone (168), 3-nonanone (188), 5-nonanone (187), 4-hydroxy-4-methyl-2-pentanone (166), 2-methylcyclohexanone (163), 3-methylcyclohexanone (170), 4-methylcyclohexanone (170), 2,6-dimethylcyclohexanone (175), 2,2,6-trimethylcyclohexanone (179), cycloheptanone (179), hexylacetate (169), amylbutyrate (185), isopropyl lactate (167), butyllactate (186), ethyl-3-hydroxybutyrate (170), ethyl-3-ethoxypropionate (170), ethyl-3-hydroxy butyrate (180), propyl-2-hydroxy-propionate (169), propyleneglycoldiacetate (186), propyleneglycolbutylether (170), propyleneglycol methylether propionate (160), diethyleneglycol dimethyl ether (162), diethyleneglycol dimethyl ether acetate (165), dipropyleneglycolmethylether (188), dipropyleneglycoldimethylether (171), ethyleneglycolbutylether (171), diethyleneglycolmethylethylether (176), diethyleneglycolmethylisopropylether (179), diethyleneglycoldiethylether (189), butylbutyrate (165), ethyl-3-ethoxypropionate (170), diethyleneglycolmonomethylether (194), 4-ethylcyclohexanone (193), and 2-butoxyethylacetate (192), diethyleneglycolmonoethylether (202), butyrolactone (204), hexylbutylrate (205), diethyleneglycolmethyletheracetate (209), diethyleneglycolbutyl methyl ether (212), tripropylglycoldimethyl ether (215), triethyleneglycoldimethylether (216), diethyleneglycolethyletheracetate (217), diethyleneglycolbutyletheracetate (245), 3-epoxy-1,2-propanediol (222), ethyl-4-acetylbutyrate (222), diethyleneglycol monobutylether (231), tripropylglycolmethyl ether (242), diethyleneglycol (245), 2-(2-butoxyethoxy)ethylacetate (245), catechol (245), triethyleneglycol methylether (249), diethyleneglycoldibutylether (256), triethyleneglycol ethylether (256), diethyleneglycolmonohexylether (260), triethyleneglycol butylmethylether (261), triethyleneglycolbutylether (271), tripropylglycol (273), and tetraethyleneglycoldimethylether (276).

It is preferred that a coloring dispersant fabricated by mixing and milling carbon black (i.e., black pigments) and coloring pigments be used as a colorant comprising the black pigments of the present invention.

SEAST 5HIISAF-HS, SEAST KH, SEAST 3HHAF-HS, SEAST NH, SEAST 3M, SEAST 300HAF-LS, SEAST 116HMMAF-HS, SEAST 116MAF, SEAST FMFEF-HS, SEAST SOFEF, SEAST VGPF, SEAST SVHSRF-HS, and SEAST SSRF (manufactured by Tokai Carbon Co., Ltd.); DIAGRAM BLACK, DIAGRAM BLACK N339, DIAGRAM BLACK SH, DIAGRAM BLACK H, DIAGRAM LH, DIAGRAM HA, DIAGRAM SF, DIAGRAM N550M, DIAGRAM M, DIAGRAM E, DIAGRAM G, DIAGRAM R, DIAGRAM N760M, DIAGRAM LR, #2700, #2600, #2400, #2350, #2300, #2200, #1000, #980, #900, MCF88, #52, #50, #47, #45, #45L, #25, #CF9, #95, #3030, #3050, MA7, MA77, MA8, MA11, OIL7B, OIL9B, OIL11B, OIL30B, and OIL31B (manufactured by Mitsubishi Chemical Corporation)); PRINTEX-U, PRINTEX-V, PRINTEX-140U, PRINTEX-140V, PRINTEX-95, PRINTEX-85, PRINTEX-75, PRINTEX-55, PRINTEX-45, PRINTEX-300, PRINTEX-35, PRINTEX-25, PRINTEX-200, PRINTEX-40, PRINTEX-30, PRINTEX-3, PRINTEX-A, SPECIAL BLACK-550, SPECIAL BLACK-350, SPECIAL BLACK-250, SPECIAL BLACK-100, and LAMP BLACK-101 (manufactured by Degussa Japan Co., Ltd.); and RAVEN-1100ULTRA, RAVEN-1080ULTRA, RAVEN-1060ULTRA, RAVEN-1040, RAVEN-1035, RAVEN-1020, RAVEN-1000, RAVEN-890H, RAVEN-890, RAVEN-880ULTRA, RAVEN-860ULTRA, RAVEN-850, RAVEN-820, RAVEN-790ULTRA, RAVEN-780ULTRA, RAVEN-760ULTRA, RAVEN-520, RAVEN-500, RAVEN-460, RAVEN-450, RAVEN-430ULTRA, RAVEN-420, RAVEN-410, RAVEN-2500ULTRA, RAVEN-2000, RAVEN-1500, RAVEN-1255, RAVEN-1250, RAVEN-1200, RAVEN-1190ULTRA, and RAVEN-1170 (manufactured by Columbia Carbon Co., Ltd.) can be used as the carbon black either solely or in combinations.

Coloring pigments which can be mixed with the carbon black include Carmine 6B (C.I.12490), Phthalocyanine Green (C.I.74260), Phthalocyanine Blue (C.I.74160), MITSUBISHI Carbon Black MA100, Perylene Black (BASF K0084. K0086), Cyanine Black, Linolyellow (C.I. 21090), Linolyellow GRO (C.I.21090), Benzidine Yellow4T-564D, MITSUBISHI Carbon Black MA-40, VictoriaPure Blue (C.I.42595), C.I. Pigment RED97, 122, 149, 168, 177, 180, 192, 215, C.I. Pigment Green 7, 36, C.I. Pigment 15:1, 15:4, 15:6, 22, 60, 64, C.I. Pigment 83, 139, and C.I. Pigment Violet 23. In addition to the coloring pigments, white pigments and fluorescent pigments may be used.

Meanwhile, it is preferred that the carbon black be included in an amount of 10 to 30 wt % based on the total weight of the colorant including the carbon black.

Further, the photosensitive resin composition of the present invention can further include one or more of primary additives selected from among a surfactant, a dispersant, an antioxidant, an ultraviolet absorbent, a thermal polymerization inhibitor, and a leveling agent.

The surfactant can include MCF 350SF, F-475, F-488, F-552, etc. (manufactured by DIC Corporation), but not limited thereto. The range of the surfactant can be expanded according to circumstances.

All dispersants and leveling agents which are, in general, known to those skilled in the art can be used as the dispersant and the leveling agent.

2,2-thiobis(4-methyl-6-t-butylphenol), 2,6-g,t-butylphenol, and so on can be used as the antioxidant. 2-(3-t-butyl-5-methyl-2-hydroxyphenyl)-5-chloro-benzotriazole, alkoxy benzophenone, and so on can be used as the ultraviolet absorbent. Hydroquinone, p-methoxyphenol, di-t-butyl-p-cresol, pyrogallol, t-butylcatechol, benzoquinone, 4,4-thiobis(3-methyl-6-t-butylphenol), 2,2-methylenebis(4-methyl-6-t-butylphenol), 2-mercaptoimidazole, and so on can be used as the thermal polymerization inhibitor.

Furthermore, the photosensitive resin composition of the present invention can further include one or more of secondary additives selected from among carbon black dispersion substance, a resin binder having a function, monomer, a radiation-sensitive compound, and other additives.

Meanwhile, the present invention provides a black matrix for a liquid crystal display including the photosensitive resin composition.

More particularly, the present invention provides a black matrix for a liquid crystal display which is fabricated by coating the photosensitive resin composition on a glass using a slit coater and exposing and developing a composition coated.

### Embodiment

### Embodiment 1

The carbon dispersant (BK-123 manufactured by Mikuni Pigment Co., Ltd. and including carbon having an amount of 20%) of 950 parts by weight, an alkali-soluble Cardo type binder {bisphenol fluorene epoxy acrylate having acrylate added thereto/1,3-cyclohexyldiisocyanate (a mole ratio 65/35, Mw=5000, and an acid value of 80 KOH mg/g)} of 67.5 parts by weight, an alkali-soluble acryl type binder {benzylmethacrylate/N-phenylmaleimide/styrene/methaacrylate (a mole ratio 60/10/12/18, Mw=15000, and 80 KOH mg/g)} of 7.5 parts by weight, dipentaerythritol hexa acrylate (i.e., the multi-functional monomer) of 35 parts by weight, ethanone,-1-(9-ethyl)-6-(2-methylbenzoyl-3-yl)-,1-(O-acetyloxime) (i.e., the photopolymerization initiator) of 37 parts by weight, 3-methaacryloxypropyltrimethoxysilane (i.e., the adhesion accelerator) of 5 parts by weight, and MCF-350SF (manufactured by DIC Corporation) (i.e., the leveling agent) of 1 parts by weight, propyleneglycolmonomethyletheracetate (i.e., the solvent) of 350 parts by weight, 3-methoxybutylacetate of 1250 parts by weight, and diethyleneglycolmethylbutylether of 150 parts by weight were mixed.

Next, the mixture was stirred for 5 hours, thereby fabricating a black matrix photosensitive resin composition.

The photosensitive resin composition solution was coated on a glass using a slit coater at the rate of 150 mm/sec, subjected to decompression and drying in a VCD up to 65 Pa, and then subjected to pre-baking processing at a temperature of about 100 for 2 minutes, thereby forming a conductive film of 22 μm in thickness. Next, the photosensitive resin composition solution was cooled at normal temperature and then exposed to energy of 30 mJ/cm² under a high-pressure mercury lamp using a photomask. The exposed substrate was developed in a KOH aqueous solution of 0.04% using a spray method at a temperature of 25, washed using pure water, dried, and then post-baked in a convection oven of 230 for 20 minutes.

The film acquired as described was a clean conductive film with no surface detects according to each process. The film had a film thickness of 1.1 μm, no broken pattern, and an excellent straight property.

### Embodiment 2

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 65 parts by weight and an alkali-soluble acryl type binder {benzylmethaacryllake/N-phenylmaleimide/styrene/methaacrylate (a mole ratio 55/9/11/25, Mw=20000, and 100 KOH mg/g)} of 10 parts by weight were used.

A conductive film formed through the same processes as those of the embodiment 1 was a clean conductive film with no surface detects according to each process. The film had a film thickness of 1.1 μm, no broken pattern, and an excellent straight property.

### Embodiment 3

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 60 parts by weight and an alkali-soluble acryl type binder {benzylmethaacryllake/N-phenylmaleimide/styrene/methaacrylate (a mole ratio 55/9/11/25, Mw=20000, and 100 KOH mg/g)} of 15 parts by weight were used.

A conductive film formed through the same processes as those of the embodiment 1 was a clean conductive film with no surface detects according to each process. The film had a film thickness of 1.1 μm, no broken pattern, and an excellent straight property.

### Embodiment 4

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 45 parts by weight and an alkali-soluble acryl type binder {benzylmethaacryllake/N-phenylmaleimide/styrene/methaacrylate (a mole ratio 55/9/11/25, Mw=20000, and 100 KOH mg/g)} of 30 parts by weight were used. A conductive film formed through the same processes as those of the embodiment 1 was a clean conductive film with no surface detects according to each process. The film had a film thickness of 1.1 μm, no broken pattern, and an excellent straight property.

### Embodiment 5

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 30 parts by weight and an alkali-soluble acryl type binder {benzylmethacrylate/N-phenylmaleimide/styrene/methaacrylate/laurylmethaacryllate (a mole ratio 52/9/11/18/10, Mw=15000, and 78 KOH mg/g)} of 45 parts by weight were used.

A conductive film formed through the same processes as those of the embodiment 1 was a clean conductive film with no surface detects according to each process. The film had a film thickness of 1.1 μm, no broken pattern, and an excellent straight property.

### Embodiment 6

A black matrix photosensitive resin composition was fabricated using the same method as that of the embodiment 1 except that an alkali-soluble Cardo type binder{bisphenol fluorene epoxy acrylate having acrylate added thereto/1,3-cyclohexyldiisocyanate (a mole ratio 65/35, Mw=5000, and an acid value 80 KOH mg/g)} of 20 parts by weight and an alkali-soluble acryl type binder {benzylmethacrylate/N-phenylmaleimide/styrene/methaacrylate (a mole ratio 60/10/12/18, Mw=15000, and 80 KOH mg/g)} of 55 parts by weight were used.

A conductive film formed through the same processes as those of the embodiment 1 was a clean conductive film with no surface detects according to each process. The film had a film thickness of 1.1 μm, no broken pattern, and an excellent straight property.

### Embodiment 7

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 15 parts by weight and an alkali-soluble acryl type binder {benzylmethaacryllake/N-phenylmaleimide/styrene/methaacrylate (a mole ratio 55/9/11/25, Mw=20000, and 100 KOH mg/g)} of 60 parts by weight were used.

A conductive film formed through the same processes as those of the embodiment 1 was a generally clean conductive film with almost no surface detects according to each process. The film had a film thickness of 1.1 μm, almost no broken pattern, and an excellent straight property.

### Embodiment 8

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 10 parts by weight and an alkali-soluble acryl type binder {benzylmethaacryllake/N-phenylmaleimide/styrene/methaacrylate (a mole ratio 55/9/11/25, Mw=20000, and 100 KOH mg/g)} of 65 parts by weight were used.

A conductive film formed through the same processes as those of the embodiment 1 was a generally clean conductive film with almost no surface detects according to each process. The film had a film thickness of 1.1 μm, almost no broken pattern, and an excellent straight property.

### Embodiment 9

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 7.5 parts by weight and an alkali-soluble acryl type binder {benzylmethacrylate/N-phenylmaleimide/styrene/methaacrylate (a mole ratio 60/10/12/18, Mw=15000, and 80 KOH mg/g)} of 67.5 parts by weight were used.

A conductive film formed through the same processes as those of the embodiment 1 was a generally clean conductive film with almost no surface detects according to each process. The film had a film thickness of 1.1 μm, almost no broken pattern, and an excellent straight property.

### Comparison Example

### Comparison Example 1

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 75 parts by weight was solely used as the binder.

A conductive film formed through the same processes as those of the embodiment 1 was a clean conductive film with no surface detects according to each process. The film had a film thickness of 1.1 μm, no broken pattern, and an excellent straight property.

### Comparison Example 2

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 71.25 parts by weight and an alkali-soluble acryl type binder {benzylmethacrylate/N-phenylmaleimide/styrene/methaacrylate (a mole ratio 60/10/12/18, Mw=15000, and 80 KOH mg/g)} of 3.75 parts by weight were used.

A conductive film formed through the same processes as those of the embodiment 1 was a clean conductive film with no surface detects according to each process. The film had a film thickness of 1.1 μm, almost no broken pattern, and an excellent straight property.

### Comparison Example 3

A black matrix photosensitive resin composition was fabricated using the same method as that of the embodiment 1 except that an alkali-soluble Cardo type binder {bisphenol fluorene epoxy acrylate having acrylate added thereto/1,3-cyclohexyldiisocyanate (a mole ratio 65/35, Mw=5000, and an acid value 80 KOH mg/g)} of 3.75 parts by weight and an alkali-soluble acryl type binder {benzylmethacrylate/N-phenylmaleimide/styrene/methaacrylate (a mole ratio 60/10/12/18, Mw=15000, and 80 KOH mg/g)} of 71.25 parts by weight were used.

A conductive film formed through the same processes as those of the embodiment 1 had a severe broken pattern during a development process, making it impossible to obtain a clean pattern.

### Comparison Example 4

A black matrix photosensitive resin composition was fabricated using the same method as that of the embodiment 1 except that an alkali-soluble acryl type binder {benzylmethacrylate/N-phenylmaleimide/styrene/methaacrylate (a mole ratio 60/10/12/18, Mw=15000, and 80 KOH mg/g)} of 75 parts by weight was solely used as the binder.

A conductive film formed through the same processes as those of the embodiment 1 had a severe broken pattern during a development process, making it impossible to obtain a clean pattern.

### Experiment Examples

### Evaluation of Adhesion Properties

When the conductive films were formed using the photosensitive resin compositions according to the embodiments and the comparison examples, the conductive films on which up to the exposure process was performed was not developed and post-baked in the convection oven of 230 for 100 minutes. In this state, a Pressure-Cooker Test (PCT) was evaluated.

The PCT process conditions were 2 atmospheric pressure and humidity of 120%. In this case, 4 hours was one cycle.

TABLE 1
<Evaluation results of process characteristic and adhesion
properties of the embodiments and the comparison examples>

| | Em. 1 | Em. 2 | Em. 3 | Em. 4 | Em. 5 | Em. 6 | Em. 7 | Em. 8 | Em. 9 | Co. 1 | Co. 2 | Co. 3 | Co. 4 |
|---|---|---|---|---|---|---|---|---|---|---|---|---|---|
| Cardo | 90/10 | 87/13 | 80/20 | 60/40 | 40/60 | 27/73 | 20/80 | 13/87 | 10/90 | 100/0 | 95/5 | 5/95 | 0/100 |
| type/acryl | | | | | | | | | | | | | |
| type wt % | | | | | | | | | | | | | |
| Process | | | | | | | ∘ | ∘ | ∘ | | | x | x |
| characteristic | | | | | | | | | | | | | |
| Adhesion | ∘ | ∘ | ∘ | | | | | | | x | | | |
| properties | | | | | | | | | | | | | |
| (4 h/1cycle) | | | | | | | | | | | | | |
| Adhesion | | ∘ | ∘ | | | | | | | x | x | | |
| Properties | | | | | | | | | | | | | |
| (8 h/2cycle) | | | | | | | | | | | | | |
| Adhesion | | | ∘ | | | | | | | x | x | | |
| properties | | | | | | | | | | | | | |
| (12 h/3cycle) | | | | | | | | | | | | | |

: Very excellent
∘: Excellent
: Poor
x: Very poor

In Table 1, ‘Em.’ indicates an embodiment, and ‘Co.’ indicates a comparison example.

Consequently, when a black matrix photosensitive resin composition for a high OD was fabricated in accordance with the present invention, a Cardo type and an acryl type were mixed and used as the binder, and ratios thereof were limited. Accordingly, a process margin could be optimized and the adhesion properties of a conductive film formed therefrom could be improved.

The black matrix photosensitive resin composition according to the present invention provides both high light-shielding and excellent adhesion properties in a black matrix for a liquid crystal display and has excellent adaptability to mobile displays to which a new coalescence technology is applied because it does not have a seal breakdown, etc. in the coalescence step and the reliability evaluation step.

While some exemplary embodiments of the present invention have been described with reference to the accompanying drawings, those skilled in the art can change and modify the present invention in various ways without departing from the essential characteristic of the present invention. Accordingly, the disclosed embodiments should not be construed to limit the technical spirit of the present invention, but should be construed to illustrate the technical spirit of the present invention. The scope of the technical spirit of the present invention is not limited by the embodiments. The scope of the present invention should be interpreted according to the following appended claims. Accordingly, the present invention should be construed to cover all modifications or variations induced from the meaning and scope of the appended claims and their equivalents.

What is claimed is:

1. A black matrix photosensitive resin composition, comprising:
a) an alkali-soluble binder resin,
b) a multi-functional monomer having an ethylenic unsaturated double bond,
c) a photopolymerization initiator,
d) an adhesion accelerator,
e) a solvent, and
f) a colorant comprising black pigments,
wherein the alkali-soluble binder resin comprises a Cardo type binder in an amount of 10 to 90 wt % based on a total weight of the alkali-soluble binder resin and an acryl type binder in an amount of 10 to 90 wt % based on the total weight of the alkali-soluble binder resin.

2. The black matrix photosensitive resin composition of claim 1, wherein the Cardo type binder is in an amount of 13 to 87 wt % based on the total weight of the alkali-soluble binder resin and an acryl type binder in an amount of 13 to 87 wt % based on the total weight of the alkali-soluble binder resin.

3. The black matrix photosensitive resin composition of claim 1, wherein the Cardo type binder is in an amount of 20 to 80 wt % based on the total weight of the alkali-soluble binder resin and an acryl type binder in an amount of 20 to 80 wt % based on the total weight of the alkali-soluble binder resin.

4. The black matrix photosensitive resin composition of claim 1, wherein the Cardo type binder is in an amount of 40 to 60 wt % based on the total weight of the alkali-soluble binder resin and an acryl type binder in an amount of 40 to 60 wt % based on the total weight of the alkali-soluble binder resin.

5. The black matrix photosensitive resin composition of claim 1, wherein
a) the alkali-soluble binder resin is in an amount of 1 to 10 parts by weight;
b) the multi-functional monomer is in an amount of 1 to 10 parts by weight;
c) the photopolymerization initiator is in an amount of 0.1 to 10 parts by weight;
d) the adhesion accelerator is in an amount of 0.01 to 1 parts by weight;
e) the solvent is in an amount of 70 to 90 parts by weight; and
f) the colorant is in an amount of 35 to 85 parts by weight.

6. The black matrix photosensitive resin composition of claim 1, wherein the Cardo type binder comprises a repetition unit represented by Formula 1 below: 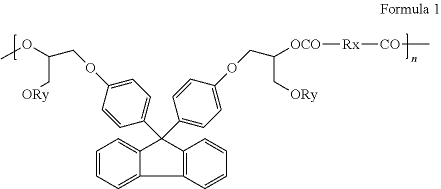
wherein Rx is carboxylic anhydride or diisocyanate;
Ry is selected from the group consisting of hydrogen, acryloyl, and methacryloyl; and
n is an integer.

7. The black matrix photosensitive resin composition of claim 1, wherein
the acryl type binder comprises a monomer providing a mechanical strength of a film and a monomer providing alkali solubility;
the monomer providing a mechanical strength of a film is selected from the group consisting of unsaturated carboxylic esters, aromatic vinyls, unsaturated ethers, unsaturated imides, and maleic anhydrides; and
the monomer providing alkali solubility is selected from the group consisting of (metha)acrylate, crotonate, itaconic acid, maleic acid, fumarate, monomethyl maleic acid, 5-norbornene-2-carboxylate, mono-2-((metha)acryloyloxy)ethyl phthalate, mono-2-((metha)acryloyloxy)ethyl succinate, and w-carboxy polycaprolactone mono(metha)acrylate.

8. The black matrix photosensitive resin composition of claim 1, wherein the Cardo type binder has an acid value of 10 to 200 KOH mg/g and a weight average molecular weight of 1,000 to 30,000.

9. The black matrix photosensitive resin composition of claim 1, wherein the acryl type binder has an acid value of 10 to 200 KOH mg/g and a weight average molecular weight of 1,000 to 50,000.

10. The black matrix photosensitive resin composition of claim 1, wherein the multi-functional monomer is a compound having at least one unsaturated radical which can be subjected to addition and polymerization in molecules and having a boiling point of 100 or more, or is caprolactone.

11. The black matrix photosensitive resin composition of claim 10, wherein the compound is selected from the group consisting of polyethyleneglycol mono(metha)acrylate, polypropyleneglycol mono(metha)acrylate, phenoxyethyl(metha)acrylate, polyethyleneglycol-(metha)acrylate, polypropyleneglycol (metha)acrylate, trimethylolethane triacrylate, trimethylolpropane triacrylate, neopentylglycol(metha)acrylate, pentaerythritol tetraacrylate, pentaerythritol triacrylate, dipentaerythritol pentaacrylate, and dipentaerythritol hexacrylate.

12. The black matrix photosensitive resin composition of claim 1, wherein the photopolymerization initiator is selected from the group consisting of an acetophenone type compound, a biimidazole type compound, a triazine type compound, and an oxime type compound.

13. The black matrix photosensitive resin composition of claim 1, wherein the photopolymerization initiator further comprises a photo-crosslinking sensitizer in an amount of 0.01 to 10 parts by weight or a curing accelerator in an amount of 0.01 to 10 parts by weight.

14. The black matrix photosensitive resin composition of claim 13, wherein the photo-crosslinking sensitizer is selected from the group consisting of a benzophenone type compound, a fluorenone type compound, a thioxanthen type compound, a xanthone type compound, an anthraquinone type compound, an acridine type compound, a dicarbonyl compound, a phosphine oxide type compound, a benzoate type compound, an amino synergist, coumarin type compound, a calcon compound, 2-benzoylmethylene, and 3-methyl-b-naphthothiazolin.

15. The black matrix photosensitive resin composition of claim 13, wherein the curing accelerator is selected from the group consisting of 2-mercaptobenzoimidazole, 2-mercaptobenzothiazole, 2-mercaptobenzooxazole, 2,5-dimercapto-1,3,4-thiadiazol, 2-mercapto-4,6-dimethylaminopyridine, pentaerythritol-tetrakis(3-mercaptopropionate), pentaerythritol-tris(3-mercaptopropionate), pentaerythritol-tetrakis(2-mercaptoacetate), pentaerythritol-tris(2-mercaptoacetate), trimethylolpropane-tris(2-mercaptoacetate), and trimethylolpropane-tris(3-mercaptopropionate).

16. The black matrix photosensitive resin composition of claim 1, wherein the adhesion accelerator is a metha acryloyl silane coupling agent or alkyl trimethoxy silane.

17. The black matrix photosensitive resin composition of claim 1, wherein the solvent is selected from the group consisting of methyl-3-methoxy propionate, ethyleneglycol methylether, ethyleneglycol ethylether, ethyleneglycol diethylether, dibutylether, ethylpyruvate, propyleneglycol methylether, propyleneglycol methylether acetate, n-butylacetate, isobutylacetate, amylacetate, isoamylacetate, butylpropionate, isoamylpropionate, ethylbutyrate, propyl butyrate, methyl-3-methoxyisobutyrate, methylglycolrate, methyl lactate, ethyl lactate, methyl-2-hydroxyisobutylrate, ethylethoxyacetate, 2-methoxyethylacetate, ethyleneglycol-methyletheracetate, 2-ethoxyethylacetate, dibutylether, cyclopentanone, cyclohexanone, 2-hexanone, 3-hexanone, 5-methyl-2-hexanone, 2-heptanone, 3-heptanone, 4-heptanone, 2-methyl-3-heptanone, 1-methoxy-2-propanol, ethyl-2-hydroxy-propionate, ethyl-3-methoxypropionate, 2-methoxy ethylether, 3-methoxybutylacetate, 2-ethoxyethyl ether, 2-butoxyethanol, 3-ethoxy-propanol, diethyleneglycoldodecylether, dipropyleneglycolmethylether, 2,6-dimethyl-4-heptanone, 2-octanone, 3-octanone, 3-nonanone, 5-nonanone, 4-hydroxy-4-methyl-2-pentanone, 2-methylcyclohexanone, 3-methylcyclohexanone, 4-methylcyclohexanone, 2,6-dimethylcyclohexanone, 2,2,6-trimethylcyclohexanone, cycloheptanone, hexylacetate, amylbutyrate, isopropyl lactate, butyllactate, ethyl-3-hydroxybutyrate, ethyl-3-ethoxypropionate, ethyl-3-hydroxy butyrate, propyl-2-hydroxy-propionate, propyleneglycoldiacetate, propyleneglycolbutylether, propyleneglycol methylether propionate, diethyleneglycol dimethyl ether, diethyleneglycol dimethyl ether acetate, dipropyleneglycolmethylether, dipropyleneglycoldimethylether, ethyleneglycolbutylether, diethyleneglycolmethylethylether, diethyleneglycolmethylisopropylether, diethyleneglycoldiethylether, butylbutyrate, ethyl-3-ethoxypropionate, diethyleneglycolmonomethylether, 4-ethylcyclohexanone, 2-butoxyethylacetate, diethyleneglycolmonoethylether, butyrolactone, hexylbutylrate, diethyleneglycolmethyletheracetate, diethyleneglycolbutyl methyl ether, tripropylglycoldimethyl ether, triethyleneglycoldimethylether, diethyleneglycolethyletheracetate, diethyleneglycol-butyletheracetate, 3-epoxy-1,2-propanediol, ethyl-4-acetylbutyrate, diethyleneglycol monobutylether, tripropylglycolmethyl ether, diethyleneglycol, 2-(2-butoxyethoxy)ethylacetate, catechol, triethyleneglycol methylether, diethyleneglycoldibutylether, triethyleneglycol ethylether, diethyleneglycolmonohexylether, triethyleneglycol butyl methyl ether, triethyleneglycolbutylether, tripropylglycol, and tetraethyleneglycoldimethylether.

18. The black matrix photosensitive resin composition of claim 1, wherein the colorant comprises a coloring dispersant fabricated by mixing and milling carbon black and coloring pigments.

19. The black matrix photosensitive resin composition of claim 18, wherein the carbon black is in an amount of 10 to 30 wt % based on a total weight of the colorant.

20. The black matrix photosensitive resin composition of claim 1, wherein the photosensitive resin composition further comprises an additive selected from the group consisting of a surfactant, a dispersant, an antioxidant, an ultraviolet absorbent, a thermal polymerization inhibitor, and a leveling agent.
